(19) United States
(12) Patent Application Publication
(10) Pub. No.: US 2010/0173467 A1
(43) Pub. Date: Jul. 8, 2010

(54) THIN FILM AND SEMICONDUCTOR DEVICE MANUFACTURING METHOD USING THE THIN FILM

(75) Inventors: Yoshihiro Kato, Yamanashi (JP); Noriaki Fukiage, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Tokyo Electron Limited, Tokyo (JP)

(21) Appl. No.: 12/601,831

(22) PCT Filed: May 19, 2008
(86) PCT No.: PCT/JP08/59129

§ 371 Date: Jan. 14, 2010

(30) Foreign Application Priority Data
May 25, 2007 (JP) 2007-138793
Sep. 19, 2007 (JP) 2007-241939

(51) Int. Cl. H01L 21/336; H01L 21/302; H01L 21/314; H01B 1/12

(52) U.S. Cl. 438/301; 438/694; 252/500; 438/294; 257/E21.214; 257/E21.409; 257/E21.266

(57) ABSTRACT

A thin film is used in a semiconductor device manufacturing process. The thin film contains silicon, germanium, and oxygen.

### TECHNICAL FIELD

The present invention relates to a thin film that is removable after it is formed on or above a semiconductor substrate and is used for a specific function, and also relates to a semiconductor manufacturing method using the thin film.

### BACKGROUND ART

Integrated circuits have been miniaturized to improve their integration and performance levels. However, at present, since their pattern sizes are of the order of nanometer, improvement in the performance of transistors cannot be expected any more by miniaturization.

In order to solve this problem and to improve the performance of transistors, studies have been made of a technique for improving the carrier mobility of the transistors from one aspect. As a method for improving the carrier mobility of a transistor, there is a method for applying a stress to the channel of the transistor by depositing a silicon nitride (SiN) film, which has a tensile stress (in the case of an n-MOS transistor) or a compressive stress (in the case of a p-MOS transistor), directly on the transistor (for example, Jpn. Pat. Appln. KOKAI Publication No. 2007-19515).

A brief explanation will be given of this technique with reference to FIG. 19. Specifically, on a silicon substrate 11, a source 12, a drain 13, a gate insulating film 14, a gate electrode 15, a sidewall spacer 16, and a nickel silicide layer 17 are formed. These portions are covered with a silicon nitride film (SiN film) 18 or 19 having a large stress and called a stress liner. The SiN film 18 deposited on the n-MOS transistor has a tensile stress and thereby applies a tensile stress to the channel region 20. On the other hand, the SiN film 19 deposited on the p-MOS transistor has a compressive stress and thereby applies a compressive stress to the channel region 21. Consequently, the mobility of electrons is increased in the n-MOS transistor, and the mobility of holes is increased in the p-MOS transistor.

However, the sidewall spacer film 16 is disposed under each SiN film having a stress such that the stress is applied through the spacer film, and thus the stress actually applied to the channel is not so large.

In order to apply the stress more effectively, it is known that the SiN film 18 or 19 is preferably deposited directly on the gate without the sidewall spacer 16 formed therebetween (for example, Jpn. Pat. Appln. KOKAI Publication No. 2007-49166).

The sidewall spacer film 16 is a film conceived to serve as a mask for ion implantation. After the gate electrode 15 is etched, ion implantation is performed to form regions so-called extensions, and then the sidewall spacer film is formed. Then, ion implantation is performed with the sidewall spacer used as a mask to form deep diffusion layers, thereby completing the source 12 and drain 13.

As described above, the sidewall spacer film is used as a mask for ion implantation, and so this film is required to be stable in the ion implantation atmosphere and to be stable in a mixture solution of sulfuric acid/hydrogen peroxide for removing a resist used for the ion implantation. Accordingly, an SiN film is used for this purpose, in general.

As well known, SiN films are stable and are not dissolved by a mixture solution of sulfuric acid/hydrogen peroxide. Only thermal phosphoric acid is used as an etching solution for dissolving SiN films. However, even where the thermal phosphoric acid is used, the etching rate of SiN films is low, and so it takes a long time to remove the sidewall spacer film. Therefore, when the sidewall spacer film is removed, the nickel silicide layer 17 is also etched, and the resistance of the diffusion layers (the source 12 and drain 13) is increased. In light of this problem, there are demands for a technique for etching the sidewall spacer film in a short time to prevent the nickel silicide layer 17 from being etched.

As described above, where the sidewall spacer film is removed to effectively apply a stress to the channel, the nickel silicide layer on the source 12 and drain 13 is also etched and increases its resistance.

### DISCLOSURE OF INVENTION

An object of the present invention is to provide a thin film that can be used as a thin film for semiconductor devices, such as the sidewall spacer film, and can be swiftly removed without etching another film, such as a nickel silicide layer, and to provide a semiconductor device manufacturing method using the thin film.

According to a first aspect of the present invention, there is provided a thin film to be used in a semiconductor device manufacturing process, wherein the thin film contains silicon, germanium, and oxygen.

According to a second aspect of the present invention, there is provided a semiconductor device manufacturing method comprising: forming a thin film containing silicon, germanium, and oxygen; exposing the thin film to etching; and removing the thin film remaining after said exposing the thin film to etching.

According to a third aspect of the present invention, there is provided a semiconductor device manufacturing method comprising: forming a gate electrode on or above an active region of a semiconductor layer including the active region and a device isolation region; forming sidewall spacers, each of which is a thin film containing silicon, germanium, and oxygen, respectively on side surfaces of the gate electrode by use of a material different from those of the semiconductor layer, the device isolation region, and the gate electrode; introducing an impurity into the active region while using the device isolation region, the gate electrode, and the sidewall spacers as a mask, thereby forming source and drain regions in the active region; covering the semiconductor layer, the device isolation region, the sidewall spacers, and the gate electrode with a metal film; causing the metal film to react with the semiconductor layer and the gate electrode, thereby lowering resistivity of part the source and drain regions and the gate electrode; removing a non-reacted portion of the metal film by use of a first etchant that easily etches the non-reacted portion of the metal film and hardly etches the device isolation region, a resistivity-lowered portion of the gate electrode, a resistivity-lowered portion of the source and drain regions, and the sidewall spacers; and removing the sidewall spacers by use of a second etchant that easily etches the sidewall spacers and hardly etches the device isolation region, the resistivity-lowered portion of the gate electrode, and the resistivity-lowered portion of the source and drain regions.

According to a fourth aspect of the present invention, there is provided a semiconductor device manufacturing method comprising: forming gate electrodes respectively on or above a first conductivity type active region and a second conductivity type active region of a semiconductor layer including the first conductivity type active region, the second conductivity type active region, and a device isolation region; forming sidewall spacers, each of which is a thin film containing silicon, germanium, and oxygen, respectively on side surfaces of the gate electrode formed on or above the first conductivity type active region and side surfaces of the gate electrode formed on or above the second conductivity type active region by use of a material different from those of the semiconductor layer, the device isolation region, and the gate electrodes; covering a region of the semiconductor layer, in which a first conductivity type transistor is to be formed, with a first mask material; introducing an impurity into the first conductivity type active region while using the device isolation region, the gate electrode formed on the first conductivity type active region, the sidewall spacers formed on the side surfaces of this gate electrode, and the first mask material as a mask, thereby forming second conductivity type source and drain regions in the first conductivity type active region; removing the first mask material and then covering a region of the semiconductor layer, in which a second conductivity type transistor is to be formed, with a second mask material; introducing an impurity into the second conductivity type active region while using the device isolation region, the gate electrode formed on the second conductivity type active region, the sidewall spacers formed on the side surfaces of this gate electrode, and the second mask material as a mask, thereby forming first conductivity type source and drain regions in the second conductivity type active region; removing the second mask material and then covering the semiconductor layer, the device isolation region, the sidewall spacers, and the gate electrodes with a metal film; causing the metal film to react with the semiconductor layer and the gate electrodes, thereby lowering resistivity of part the source and drain regions and the gate electrodes; removing a non-reacted portion of the metal film by use of a first etchant that easily etches the non-reacted portion of the metal film and hardly etches the device isolation region, a resistivity-lowered portion of the gate electrodes, a resistivity-lowered portion of the source and drain regions, and the sidewall spacers; and removing the sidewall spacers by use of a second etchant that easily etches the sidewall spacers and hardly etches the device isolation region, the resistivity-lowered portion of the gate electrodes, and the resistivity-lowered portion of the source and drain regions.

### BRIEF DESCRIPTION OF DRAWINGS

FIG. 1 This is a view showing the etching rates of thin films according to an embodiment of the present invention in a mixture solution of sulfuric acid/hydrogen peroxide and the etching rate of the thin film in phosphoric acid.

FIG. 2 This is a view showing infrared spectroscopic charts of films according to an embodiment of the present invention.

FIG. 3 This is a view showing an effect of a thin film according to an embodiment of the present invention.

FIG. 4A This is a view showing results of a composition analysis.

FIG. 4B This is a view showing results of a composition analysis.

FIG. 5A This is a view showing results of a composition analysis.

FIG. 5B This is a view showing results of a composition analysis.

FIG. 6 This is a sectional view showing a main step of a semiconductor device manufacturing method according to a present example of the present invention.

FIG. 7 This is a sectional view showing a main step of the semiconductor device manufacturing method according to a present example of the present invention.

FIG. 8 This is a sectional view showing a main step of the semiconductor device manufacturing method according to a present example of the present invention.

FIG. 9 This is a sectional view showing a main step of the semiconductor device manufacturing method according to a present example of the present invention.

FIG. 10 This is a sectional view showing a main step of the semiconductor device manufacturing method according to a present example of the present invention.

FIG. 11 This is a sectional view showing a main step of the semiconductor device manufacturing method according to a present example of the present invention.

FIG. 12 This is a sectional view showing a main step of the semiconductor device manufacturing method according to a present example of the present invention.

FIG. 13 This is a sectional view showing a main step of the semiconductor device manufacturing method according to a present example of the present invention.

FIG. 14 This is a sectional view showing a main step of the semiconductor device manufacturing method according to a present example of the present invention.

FIG. 15 This is a sectional view showing a main step of the semiconductor device manufacturing method according to a present example of the present invention.

FIG. 16 This is a sectional view showing a main step of the semiconductor device manufacturing method according to a present example of the present invention.

FIG. 17 This is a sectional view showing a main step of the semiconductor device manufacturing method according to a present example of the present invention.

FIG. 18 This is a sectional view showing a main step of the semiconductor device manufacturing method according to a present example of the present invention.

FIG. 19 This is a sectional view showing a transistor according to a conventional technique.

### BEST MODE FOR CARRYING OUT THE INVENTION

There may be two methods for achieving the object described above. One of them is a method for providing a solution that etches an SiN film without etching a nickel silicide layer. The other is a method for providing a film that can be etched at a high rate in a short time within a thermal phosphoric acid.

An embodiment is directed to the latter, and is specifically conceived to provide a film that can serve as the sidewall spacer film and can be easily etched within thermal phosphoric acid.

To reiterate, the sidewall spacer film is required to have properties, as follows.

1) Since the sidewall spacer film is conceived to serve as a mask for ion implantation, the film has to be not degenerated during the ion implantation process.

2) The sidewall spacer film has to be not etched during a process of removing a resist used for the ion implantation (an oxygen plasma ashing step and a residue removing step using a mixture solution of sulfuric acid/hydrogen peroxide).

Particularly, it is important for the sidewall spacer film not to be etched by the mixture solution of sulfuric acid/hydrogen peroxide. This embodiment is to provide a film that is not dissolved by the mixture solution of sulfuric acid/hydrogen peroxide but can be easily etched by thermal phosphoric acid.

The present inventors made assiduous studies to achieve the object described above and have arrived at the findings that a film containing silicon, germanium, and oxygen satisfies this requirement. Accordingly, this embodiment employs a film containing silicon, germanium, and oxygen as a film that serves the sidewall spacer.

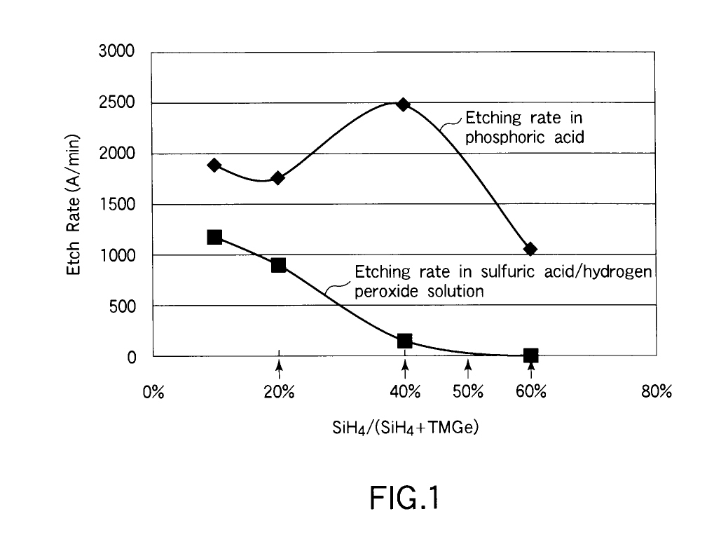

For example, FIG. 1 is a view showing the etching rates of films in a mixture solution of sulfuric acid/hydrogen peroxide and in phosphoric acid, wherein the films were formed by use of tetramethyl germanium (TMGe) and carbon dioxide as base gases and monosilane (SiH₄) added thereto. With an increase in the additive amount of monosilane gas, the etching rate in phosphoric acid becomes higher and then peaks out. On the other hand, with an increase in the additive amount of monosilane gas, the etching rate in sulfuric acid/hydrogen peroxide becomes simply lower.

As shown in FIG. 1, the basic advantage of the film containing silicon, germanium, and oxygen resides in that the etching rate of the film in phosphoric acid is always higher than the etching rate of the film in the mixture solution of sulfuric acid/hydrogen peroxide.

Based on this advantage, the film containing silicon, germanium, and oxygen provides an effect that the film can be easily etched in phosphoric acid while it can be hardly etched in the mixture solution of sulfuric acid/hydrogen peroxide.

Further, as shown in FIG. 1, where the flow rate of monosilane is set at 20% or more of the total flow rate of TMGe and monosilane, thin films thus formed show a phenomenon in that the etching rate in the mixture solution of sulfuric acid/hydrogen peroxide is gradually lower while the etching rate in phosphoric acid is gradually improved.

Based on this phenomenon, it is possible to obtain an advantage such that a thin film formed by setting the flow rate of monosilane at 20% or more of the total flow rate of the total flow rate of TMGe and monosilane will be provided with a larger difference between the etching rate in phosphoric acid and the etching rate in the mixture solution of sulfuric acid/hydrogen peroxide.

Further, where the flow rate of monosilane is set at 40% of the total flow rate of TMGe and monosilane, a thin film thus formed shows the highest value of the etching rate in phosphoric acid.

Based on this phenomenon, it is possible to obtain an advantage such that a thin film formed by setting the flow rate of monosilane at 40% of the total flow rate of TMGe and monosilane will be provided with the highest value of the etching rate in phosphoric acid.

Further, where the flow rate of monosilane is set at 50% or more of the total flow rate of TMGe and monosilane, thin films thus formed are hardly etched in the mixture solution of sulfuric acid/hydrogen peroxide.

Based on this phenomenon, it is possible to obtain an advantage such that a thin film formed by setting the flow rate of monosilane at 50% or more of the total flow rate of TMGe and monosilane will be prevented from being etched in the mixture solution of sulfuric acid/hydrogen peroxide.

However, where the flow rate of monosilane is set at 40% or more of the total flow rate of TMGe and monosilane, thin films thus formed show a phenomenon in that the etching rate in phosphoric acid is gradually decreased. Further, as regards the difference between the etching rate in phosphoric acid and the etching rate in the mixture solution of sulfuric acid/hydrogen peroxide, thin films formed by setting the flow rate of monosilane to be larger than 60% have almost the same value as that of thin films formed by setting the flow rate of monosilane to be less than 20%.

Judging from the results described above, the value range is preferably selected as follows:

1) The flow rate of monosilane is set to be 20% or more and 60% or less of the total flow rate of TMGe and monosilane.

2) The flow rate of monosilane is set at 40% of the total flow rate of TMGe and monosilane.

3) The flow rate of monosilane is set to be 50% or more and 60% or less of the total flow rate of TMGe and monosilane.

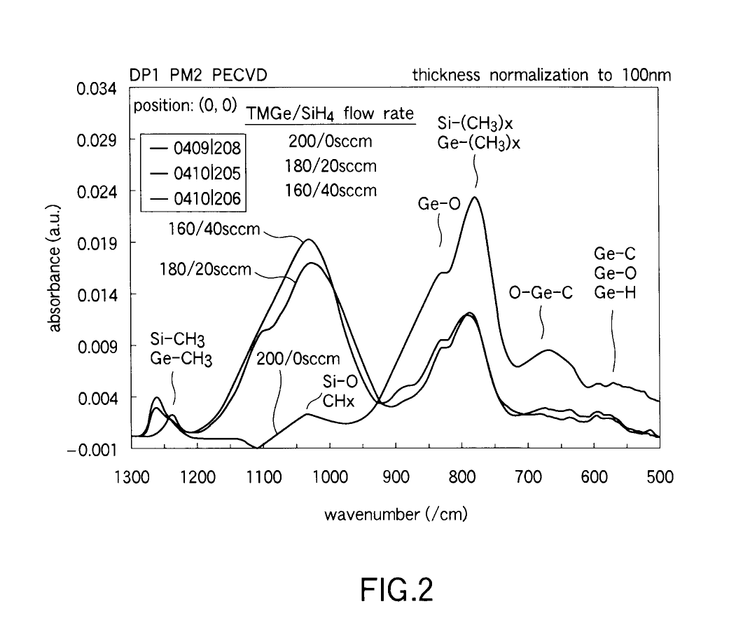

FIG. 2 shows spectrums obtained by an infrared spectroscopic analysis of the films. It is apparent from this view that an Si—O—Si stretching vibration is observed near 1,000 cm⁻¹ and an Si—O—Si network is gradually formed with an increase in the flow rate of monosilane from 0% to 20%.

In order to more accurately control the etching rate in a solution, one or both of carbon and hydrogen may be further added to a film comprising silicon, germanium, and oxygen.

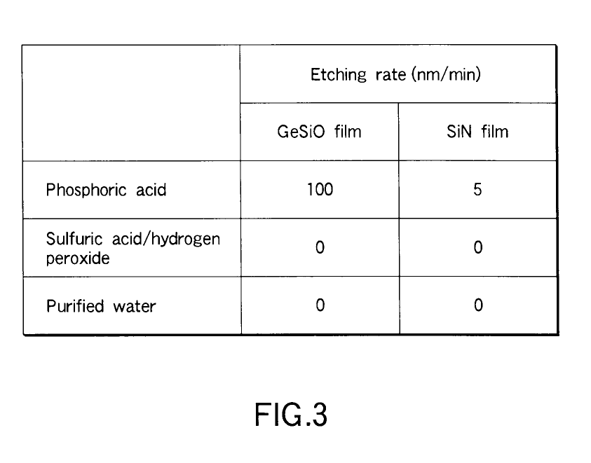

FIG. 3 is a view showing one effect according to this embodiment. The etching rate of the present film in thermal phosphoric acid exceeds 100 nm/min, which is far larger than the etching rate of an SiN film conventionally used for the same purpose. Since the sidewall spacer film has a film thickness of about 30 to 50 nm in general, the film can be etched in about 30 seconds. With this time period, the nickel silicide layer can be hardly etched. Accordingly, where a thin film according to this embodiment is used in a semiconductor device, the sidewall spacer film can be removed without increasing the resistance of the diffusion layer.

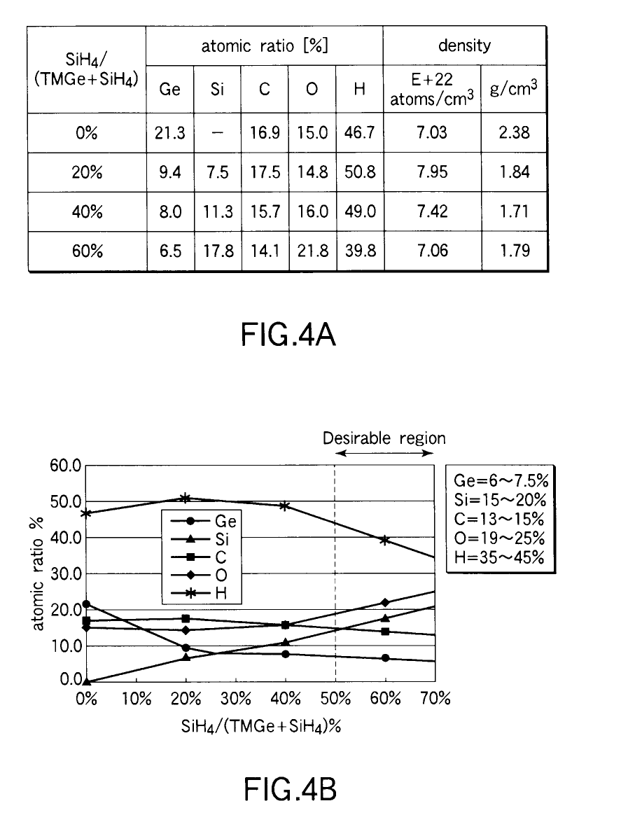

FIGS. 4A and 4B show results of a composition analysis of thin films. This composition analysis was performed by RBS (Rutherford Backscattering Spectrometry).

As shown in FIG. 4A, the components of a thin film formed only by TMGe were germanium (Ge), carbon (C), oxygen (O), and hydrogen (H). According to this analysis, the composition ratios of these components in the thin film were 21.3%, 16.9%, 15.0%, and 46.7%, respectively.

Where monosilane was supplied in addition to TMGe, a thin film thus formed came to further contain silicon (Si). With an increase in the flow rate of monosilane relative to the total flow rate of TMGe and monosilane, such as 20%, 40%, and 60%, the composition ratio of Ge was lower while the composition ratio of Si was higher in the thin film thus formed, as shown in FIG. 4A.

FIG. 4B is a sequential line graph showing the analysis results of FIG. 4A.

As shown in FIG. 4B, the composition ratios of Ge and Si reverse their magnitude relation when the flow rate of monosilane exceeds about 25%. Further, the composition ratios of C and Si reverse their magnitude relation when the flow rate of monosilane exceeds about 50%.

Incidentally, where a thin film is formed by setting the flow rate of monosilane at 50% or more of the total flow rate of TMGe and monosilane, the thin film thus formed can be hardly etched in a mixture solution of sulfuric acid/hydrogen peroxide, as described above with reference to FIG. 1. Where the components of this thin film are listed in decreasing order of composition ratio, they are H, O, Si, C, and Ge, as shown in FIG. 4B. The thin film containing H, O, Si, C, and Ge in this order is a thin film formed by setting the flow rate of monosilane at about 50% or more and 70% or less of the total flow rate of TMGe and monosilane, as shown in FIG. 4B. Specific values may be exemplified by H=35% or more and 45% or less, O=19% or more and 25% or less, Si=15% or more and 20% or less, C=13% or more and 15% or less, and Ge=6% or more and 7.5% or less.

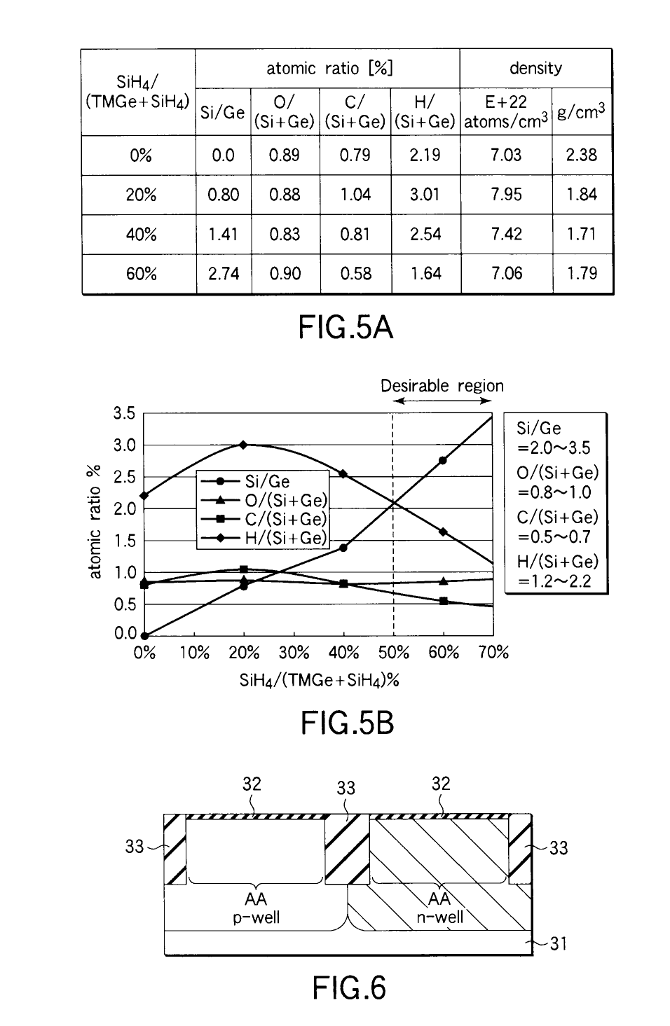

FIGS. 5A and 5B show results of a composition analysis of thin films, as in FIGS. 4A and 4B. FIG. 5A shows values calculated on the basis of the analysis results shown in FIG. 4A and denoting the ratio (Si/Ge) between Si and Ge, the ratio (O/(Si+Ge) between 0 and Si+Ge, the ratio (C/(Si+Ge)) between C and Si+Ge, and the ratio (H/(Si+Ge)) between H and Si+Ge in the formed thin films. FIG. 5B is a sequential line graph showing the values of FIG. 5A.

As shown in FIG. 5B, where the flow rate of monosilane is set at 50% or more of the total flow rate of TMGe and monosilane, the above-described ratios of this thin film are Si/Ge=2.0 or more and 3.5 or less, O/(Si+Ge)=0.8 or more and 1.0 or less, C/(Si+Ge)=0.5 or more and 0.7 or less, and H/(Si+Ge)=1.2 or more and 2.2 or less.

Next, with reference to the accompanying drawings, an explanation will be given of a specific example of a semiconductor device manufacturing method according to a present example of the present invention, wherein the method employs a thin film according to the embodiment described above.

In this present example, a film comprising silicon, germanium, and oxygen (which may be simply referred to as GeSiO, when needed) is used as a mask for an ion implantation process.

At first, as shown in FIG. 6, a p-type semiconductor region (p-well in this example) and an n-type semiconductor region (n-well in this example) are formed in a semiconductor substrate 31 made of, e.g., silicon, by use of well-known techniques. The p-well is used for forming an insulated gate field effect transistor of the n-channel type, such as an n-channel type MOSFET (n-MOS transistor). The n-well is used for forming an insulated gate field effect transistor of the p-channel type, such as a p-channel type MOSFET (p-MOS transistor). Then, device isolation regions 33 are formed by use of, e.g., STI (Shallow Trench Isolation) technique in the semiconductor substrate 31, so that active regions AA are defined on the surface area of the semiconductor substrate 31. The device isolation regions 33 are made of a material, such as silicon oxide. Then, a gate insulating film 32 made of silicon oxide is formed by, e.g., a thermal oxidation method on the active regions AA of the semiconductor substrate 31.

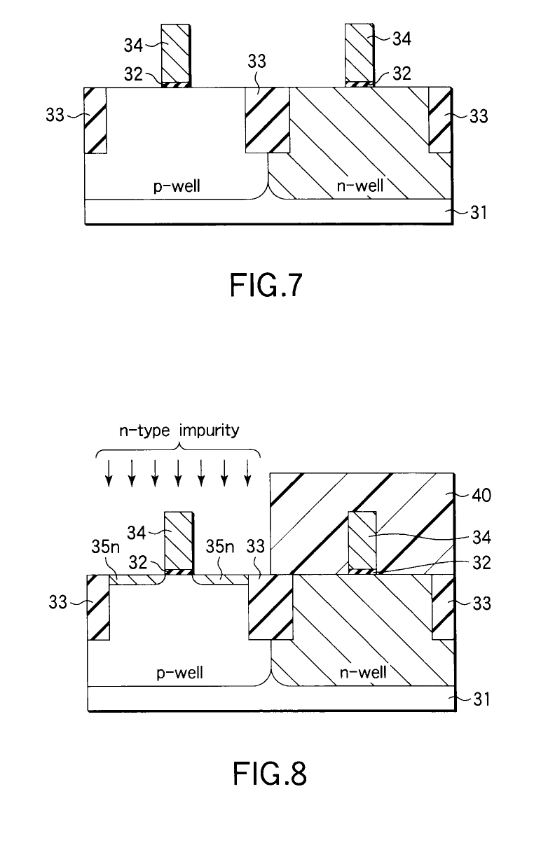

Then, as shown in FIG. 7, a conductive film is formed on the gate insulating film 32 and device isolation regions 33 and is patterned by use of a photolithography method, so that gate electrodes 34 are formed on the active region in the n-type well and the active region in the p-type well, respectively. The gate electrode 34 of the n-MOS transistor is made of a material, such as poly-silicon film or poly-silicon germanium film containing arsenic (As) or phosphorous (P) as an n-type impurity. The gate electrode 34 of the p-MOS transistor is made of a material, such as poly-silicon film or poly-silicon germanium film containing boron (B) as a p-type impurity. Alternatively, a poly-silicon film containing no impurity may be first formed and patterned by use of a photolithography method to shape gate electrodes 34. In this case, an n-type impurity is introduced by ion implantation into the gate electrode 34 formed on the p-type well and also into the p-type well. Similarly, a p-type impurity is introduced by ion implantation into the gate electrode 34 formed on the n-type well and also into the n-type well.

Then, as shown in FIG. 8, the n-type well, on which the p-MOS transistor is to be formed, is covered with a photo-resist 40. Then, an n-type impurity, such as arsenic, is introduced by ion implantation into the exposed part of the p-type well by use of the device isolation regions 33, gate electrode 34, and photo-resist 40 as a mask to form extensions 35n for the n-MOS transistor.

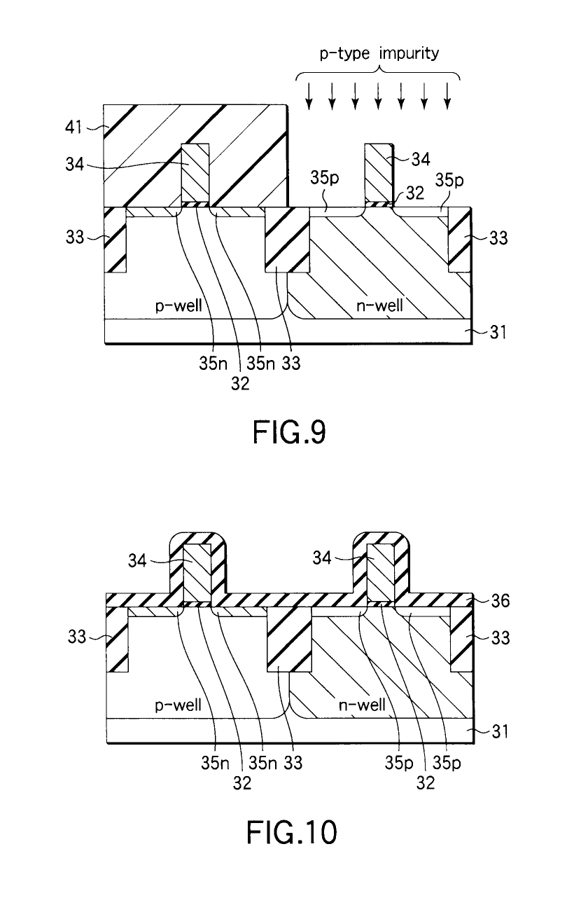

Then, as shown in FIG. 9, the photo-resist 40 is removed, and then the other side, i.e., the p-type well, on which the n-MOS transistor is to be formed, is covered with a photo-resist 41. Then, a p-type impurity, such as boron, is introduced by ion implantation into the exposed part of the n-type well by use of the device isolation regions 33, gate electrode 34, and photo-resist 41 as a mask to form extensions 35p for the p-MOS transistor.

Then, as shown in FIG. 10, the photo-resist 41 is removed, and then a thin film 36 to be used as a sidewall spacer is formed all over the semiconductor substrate 31 to cover the side surfaces and top surfaces of the gate electrodes 34 by use of a CVD method, such as a PECVD (Plasma-Enhanced CVD) method. In this example, the thin film 36 is a film containing silicon, germanium, and oxygen, such as a GeSiO film. However, the GeSiO film may further contain one or both of carbon and hydrogen to more accurately control the etching rate in a solution, as described above. For example, in this example, a GeSiCOH film is used. This GeSiCOH film may be formed by a PECVD method using tetramethyl germanium (TMGe) and carbon dioxide as base gases and monosilane (SiH₄) added thereto. As regards specific conditions for the film formation, the total flow rate of TMGe and monosilane (SiH₄) is 200 sccm. The flow rate of carbon dioxide is 2,000 sccm. The flow rate of monosilane (SiH₄) is suitably selected from the flow rate range of SiH₄/SiH₄+TMGe shown in FIG. 1. The pressure inside the chamber is 267 Pa. The substrate temperature is 300° C. Further, for example, the thickness is 30 nm to 50 nm. In this example, the thickness is set at 30 nm, for instance. As a base gas of the GeSiCOH film, in place of TMGe described above, a mixture gas of GeH₄ with a CH family gas (such as CH₄, C₂H₄, or C₂H₂) may be used. A film formation apparatus for the GeSiCOH film may be formed of a CVD apparatus using a high density plasma or a PVD apparatus, in place of the PECVD type.

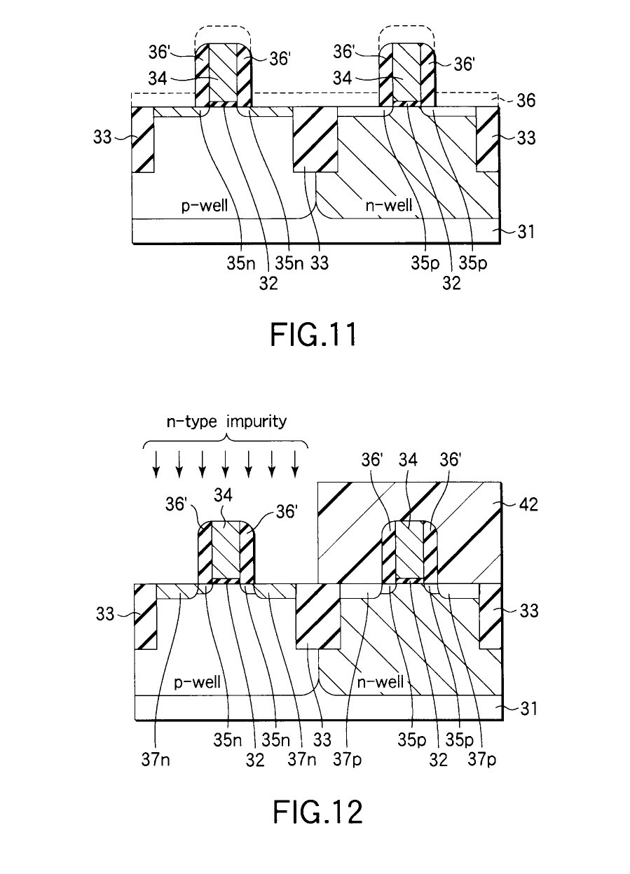

Then, as shown in FIG. 11, the thin film 36 is etched back by anisotropic etching. An example of the anisotropic etching is RIE (Reactive Ion Etching). The thin film 36 is etched back, so that a sidewall spacer 36′ formed of a GeSiCOH film is formed on each of the side surfaces of the gate electrodes 34.

Then, as shown in FIG. 12, the n-type well is covered with a photo-resist 42. Then, an n-type impurity, such as arsenic, is introduced by ion implantation into the exposed part of the p-type well by use of the device isolation regions 33, gate electrode 34, sidewall spacers 36′, and photo-resist 42 as a mask to form source and drain regions 37n for the n-MOS transistor.

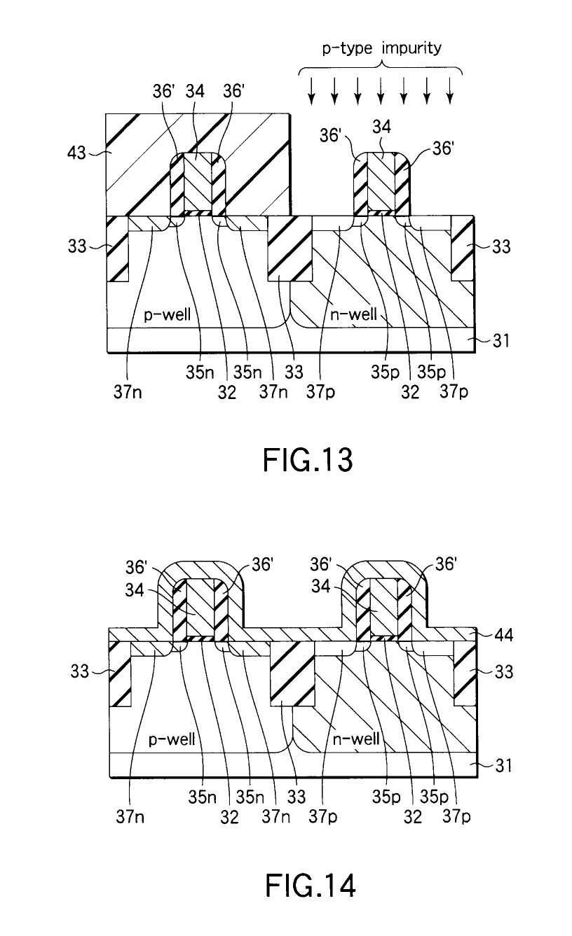

Then, as shown in FIG. 13, the photo-resist 42 is removed, and then the p-type well is covered with a photo-resist 43. Then, a p-type impurity, such as boron, is introduced by ion implantation into the exposed part of the n-type well by use of the device isolation regions 33, gate electrode 34, sidewall spacers 36′, and photo-resist 43 as a mask to form source and drain regions 37p for the p-MOS transistor. In this example, the photo-resist 42 is removed by wet etching using a mixture solution of sulfuric acid/hydrogen peroxide (SPM). A GeSiO film or a film prepared by adding one or both of carbon and hydrogen to a GeSiO film is stable in the mixture solution of sulfuric acid/hydrogen peroxide. Accordingly, the sidewall spacers 36′ are prevented from being uncontrollably removed by the wet etching for removing the photo-resist 42.

Then, as shown in FIG. 14, the photo-resist 43 is removed by wet etching using the mixture solution of sulfuric acid/hydrogen peroxide, for example. Then, a heat process is performed at a high temperature of about 1,000° C. by spike RTA (Rapid Thermal Anneal) to activate the source and drain regions 37n and 37p. Then, a metal film 44 is formed by, e.g., a sputtering method all over the semiconductor substrate 31 to cover the side surfaces and top surfaces of the gate electrodes 34. In this example, the metal film 44 is made of nickel (Ni) and is formed by a sputtering method to have a thickness of, e.g., 30 nm.

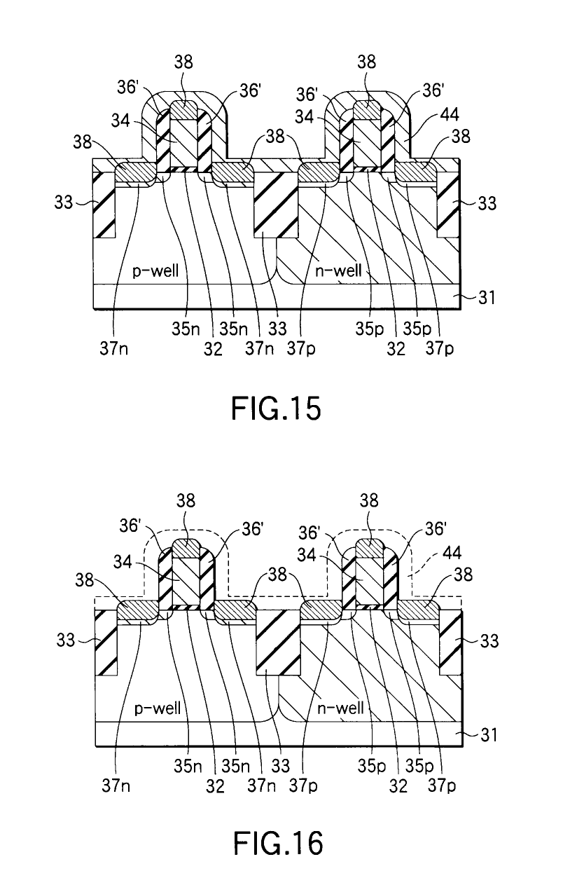

Then, as shown in FIG. 15, a heat process is performed on the structure shown in FIG. 14 with the metal film 44 formed thereon within a nitrogen atmosphere at 500° C. for 30 seconds. Consequently, the metal of the metal film 44, i.e., nickel in this example, reacts with the conductive material of the gate electrode and semiconductor substrate 31, i.e., silicon in this example, and a reaction product layer, i.e., a nickel silicide layer (NiSi) 38 in this example, is formed at each of positions where the metal film 44 and gate electrode 34 are in contact with each other and where the metal film 44 and semiconductor substrate 31 are in contact with each other (the source and drain regions 37n and 37p of the semiconductor substrate 31 in this example). The nickel silicide layers 38 thus formed lower the resistivity of part of the gate electrodes 34 and source and drain regions 37n and 37p.

Then, as shown in FIG. 16, the non-reacted portion of the metal film 44 is removed by use of an etchant that can easily etch the non-reacted portion of the metal film 44 and can hardly etch the device isolation regions 33, the resistivity-lowered portions of the gate electrodes 34 (nickel silicide layers 38), the resistivity-lowered portions of the source and drain regions (nickel silicide layers 38), and the sidewall spacers 36′. An example of such an etchant is a mixture solution of sulfuric acid/hydrogen peroxide. In this example, wet etching is performed by use of the mixture solution of sulfuric acid/hydrogen peroxide to remove the non-reacted portion of the metal film 44, i.e., nickel. Consequently, the nickel silicide layers 38 are left on the gate electrodes 34 and source and drain regions 37n and 37p. Further the sidewall spacers 36′ are also left on the side surfaces of the gate electrodes 34, because the sidewall spacers 36′ are formed of a film containing silicon, germanium, and oxygen, or a film prepared by further adding one or both of carbon and hydrogen to this film, and thus are not etched by the mixture solution of sulfuric acid/hydrogen peroxide.

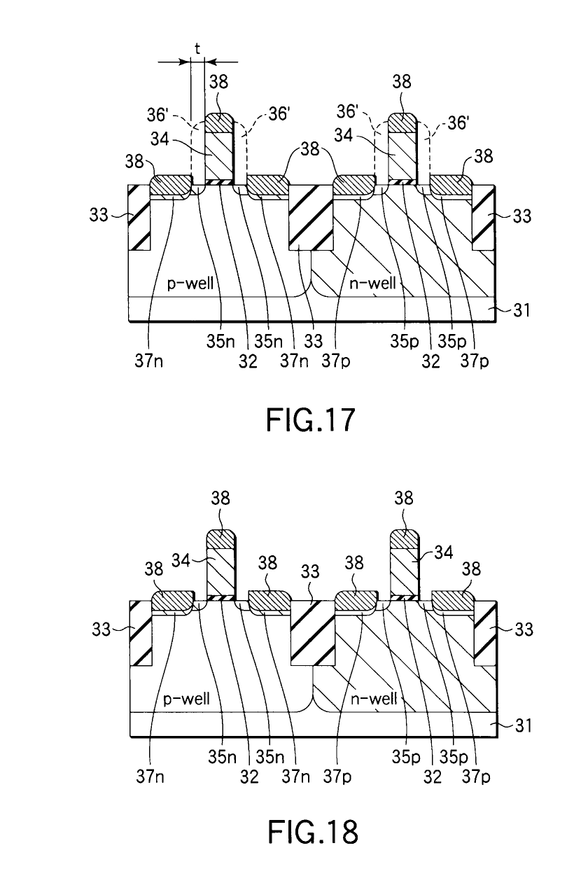

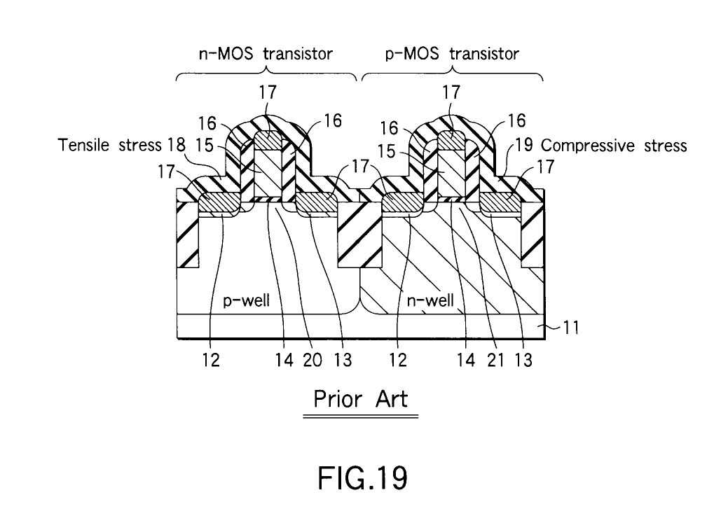

Then, as shown in FIG. 17, the sidewall spacers 36′ are removed by use of an etchant that can easily etch the sidewall spacers 36′ and can hardly etch the device isolation regions 33, the resistivity-lowered portions of the gate electrodes 34 (nickel silicide layers 38), and the resistivity-lowered portions of the source and drain regions (nickel silicide layers 38). In this example, the structure shown in FIG. 16, from which the non-reacted portion of the metal film 44 has been removed, is immersed in phosphoric acid. Since the horizontal thickness “t” of each of the sidewall spacers 36′ on the side surfaces of the gate electrodes 34 is about 30 nm and the etching makes isotropic progress, the removal of the sidewall spacers 36′ can be completed in 30 seconds even with the necessary over-etching time being considered.

Consequently, the structure shown in FIG. 18 is obtained as a semiconductor device from which the sidewall spacer films have been removed on the side surfaces of the gate electrodes 34.

As shown in FIG. 18, in the structure described above formed in accordance with this present example, the sidewall spacers are removed without etching the nickel silicide layers 38. Thereafter, for example, an SiN film is deposited directly on the gate to effectively apply a stress to each of the channel regions, thereby improving the carrier mobility of the transistors.

As described above, according to the embodiment and present example described above, there is provided a thin film that can be used as a thin film for semiconductor devices, such as the sidewall spacer film, and can be swiftly removed without etching another film, such as a nickel silicide layer, and is also provided a semiconductor device manufacturing method using the thin film.

The present invention has been explained with reference to the embodiment and present example described above, but the present invention is not limited to the embodiment and present example, and it may be modified in various manners. Further, the present example described above is not the sole present example of the present invention. For example, in the present example described above, a thin film according the embodiment is applied to a sidewall spacer that is used in a semiconductor device manufacturing process and is removed in this manufacturing process. However, a thin film that is removed in a semiconductor device manufacturing process is not limited to the sidewall spacer. A thin film according to an embodiment may be applied to a hard mask for forming a via hole or contact hole, for example.

Further, in the present example, a semiconductor layer including n-type and p-type semiconductor regions is exemplified by the semiconductor substrate 31 including the n-type well and p-type well, but the semiconductor layer is not limited to the semiconductor substrate 31. For example, the present invention may be applied to a so-called SOI substrate including a p-type semiconductor layer and an n-type semiconductor layer on an insulating film or a semiconductor thin film for forming a thin film transistor.

Further, in the present example, both of the n-MOS transistor and p-MOS transistor are formed, but the present invention may be applied to a case where only one of the n-MOS transistor and p-MOS transistor is formed. In this case, the steps of forming photo-resists 40, 41, 42, and 43 shown in FIGS. 8, 9, 12, and 13 are omitted, and only one of the n-type impurity and p-type impurity is introduced into the active region.

In the present example, the extensions 35n and 35p are formed, but they are not necessarily required even where the sidewall spacers 36′ are formed. For example, where a transistor has a smaller channel length, the extensions 35n or 35p may be connected to each other by an activation heat process, thereby bringing about a defect of short-circuiting the source and drain. Accordingly, the extensions 35n and 35p are formed only when necessary.

Further, in the present example, the sidewall spacers 36′ are formed of a film containing silicon, germanium, and oxygen and the sidewall spacers 36′ are removed.

However, for example, as described in the embodiment with reference to FIG. 1, a film containing silicon, germanium, and oxygen has an effect such that it is hardly or not etched by a mixture liquid of sulfuric acid/hydrogen peroxide. A mixture liquid of sulfuric acid/hydrogen peroxide is one of the etchants to be used in semiconductor device manufacturing processes for etching steps of removing a photo-resist and of removing a metal film, such as a nickel film. Where a film has an effect such that it is hardly or not etched by etching steps of semiconductor device manufacturing processes, the film may be used as a portion to be not necessarily removed unlike the sidewall spacers 36′ described in the present example. For example, the film may be used as an etching stopper for stopping the etching progress, or a hard mask having an opening (window) for defining an impurity doping region, for locally etching a semiconductor substrate or inter-level insulating film, or for locally causing a chemical reaction in a thin film. Since the etching stopper and hard mask are not necessarily removed from a semiconductor device but may be left in the semiconductor device. Hence, a thin film according to the embodiment, such as a thin film containing silicon, germanium, and oxygen or a thin film containing one or both of carbon and hydrogen as well as the three elements described above, may be used as a portion to be left in a semiconductor device, such as an etching stopper or hard mask.

Further, various modifications may be made to the embodiment and present example described above without departing from the spirit or scope of the present invention.

1. A thin film to be used in a semiconductor device manufacturing process, wherein the thin film contains silicon, germanium, and oxygen.

2. The thin film according to claim 1, wherein the thin film contains at least one of carbon and hydrogen in addition to the silicon, the germanium, and the oxygen.

3. The thin film according to claim 1, wherein the thin film is formed by use of tetramethyl germanium (TMGe) and carbon dioxide as base gases and monosilane (SiH₄) added thereto, and
a flow rate of the monosilane is set to be 20% or more and 60% or less of a total flow rate of the tetramethyl germanium and the monosilane.

4. The thin film according to claim 1, wherein the thin film is formed by use of tetramethyl germanium (TMGe) and carbon dioxide as base gases and monosilane (SiH₄) added thereto, and
a flow rate of the monosilane is set at 40% of a total flow rate of the tetramethyl germanium and the monosilane.

5. The thin film according to claim 1, wherein the thin film is formed by use of tetramethyl germanium (TMGe) and carbon dioxide as base gases and monosilane (SiH₄) added thereto, and
a flow rate of the monosilane is set to be 50% or more and 60% or less of a total flow rate of the tetramethyl germanium and the monosilane.

6. A semiconductor device manufacturing method comprising:
forming a thin film containing silicon, germanium, and oxygen;
exposing the thin film to etching; and
removing the thin film remaining after said exposing the thin film to etching.

7. The semiconductor device manufacturing method according to claim 6, wherein the thin film contains at least one of carbon and hydrogen in addition to the silicon, the germanium, and the oxygen.

8. A semiconductor device manufacturing method comprising:
forming a gate electrode on or above an active region of a semiconductor layer including the active region and a device isolation region;
forming sidewall spacers, each of which is a thin film containing silicon, germanium, and oxygen, respectively on side surfaces of the gate electrode by use of a material different from those of the semiconductor layer, the device isolation region, and the gate electrode;
introducing an impurity into the active region while using the device isolation region, the gate electrode, and the sidewall spacers as a mask, thereby forming source and drain regions in the active region;
covering the semiconductor layer, the device isolation region, the sidewall spacers, and the gate electrode with a metal film;
causing the metal film to react with the semiconductor layer and the gate electrode, thereby lowering resistivity of part the source and drain regions and the gate electrode;
removing a non-reacted portion of the metal film by use of a first etchant that easily etches the non-reacted portion of the metal film and hardly etches the device isolation region, a resistivity-lowered portion of the gate electrode, a resistivity-lowered portion of the source and drain regions, and the sidewall spacers; and
removing the sidewall spacers by use of a second etchant that easily etches the sidewall spacers and hardly etches the device isolation region, the resistivity-lowered portion of the gate electrode, and the resistivity-lowered portion of the source and drain regions.

9. A semiconductor device manufacturing method comprising:
forming gate electrodes respectively on or above a first conductivity type active region and a second conductivity type active region of a semiconductor layer including the first conductivity type active region, the second conductivity type active region, and a device isolation region;
forming sidewall spacers, each of which is a thin film containing silicon, germanium, and oxygen, respectively on side surfaces of the gate electrode formed on or above the first conductivity type active region and side surfaces of the gate electrode formed on or above the second conductivity type active region by use of a material different from those of the semiconductor layer, the device isolation region, and the gate electrodes;
covering a region of the semiconductor layer, in which a first conductivity type transistor is to be formed, with a first mask material;
introducing an impurity into the first conductivity type active region while using the device isolation region, the gate electrode formed on the first conductivity type active region, the sidewall spacers formed on the side surfaces of this gate electrode, and the first mask material as a mask, thereby forming second conductivity type source and drain regions in the first conductivity type active region;
removing the first mask material and then covering a region of the semiconductor layer, in which a second conductivity type transistor is to be formed, with a second mask material;
introducing an impurity into the second conductivity type active region while using the device isolation region, the gate electrode formed on the second conductivity type active region, the sidewall spacers formed on the side surfaces of this gate electrode, and the second mask material as a mask, thereby forming first conductivity type source and drain regions in the second conductivity type active region;
removing the second mask material and then covering the semiconductor layer, the device isolation region, the sidewall spacers, and the gate electrodes with a metal film;
causing the metal film to react with the semiconductor layer and the gate electrodes, thereby lowering resistivity of part the source and drain regions and the gate electrodes;
removing a non-reacted portion of the metal film by use of a first etchant that easily etches the non-reacted portion of the metal film and hardly etches the device isolation region, a resistivity-lowered portion of the gate electrodes, a resistivity-lowered portion of the source and drain regions, and the sidewall spacers; and
removing the sidewall spacers by use of a second etchant that easily etches the sidewall spacers and hardly etches the device isolation region, the resistivity-lowered portion of the gate electrodes, and the resistivity-lowered portion of the source and drain regions.

10. The semiconductor device manufacturing method according to claim 8, wherein the sidewall spacers contain at least one of carbon and hydrogen in addition to the silicon, the germanium, and the oxygen.

11. The semiconductor device manufacturing method according to claim 9, wherein the sidewall spacers contain at least one of carbon and hydrogen in addition to the silicon, the germanium, and the oxygen.

12. The semiconductor device manufacturing method according to claim 8, wherein the first etchant is a mixture liquid containing sulfuric acid and hydrogen peroxide.

13. The semiconductor device manufacturing method according to claim 9, wherein the first etchant is a mixture liquid containing sulfuric acid and hydrogen peroxide.

14. The semiconductor device manufacturing method according to claim 8, wherein the second etchant is phosphoric acid.

15. The semiconductor device manufacturing method according to claim 9, wherein the second etchant is phosphoric acid.

16. The semiconductor device manufacturing method according to claim 12, wherein the metal film contains nickel.

17. The semiconductor device manufacturing method according to claim 13, wherein the metal film contains nickel.

18. The semiconductor device manufacturing method according to claim 14, wherein the metal film contains nickel.

19. The semiconductor device manufacturing method according to claim 15, wherein the metal film contains nickel.
